(19) United States
(12) Patent Application Publication
(10) Pub. No.: US 2001/0006701 A1
(43) Pub. Date: Jul. 5, 2001

(54) CVD apparatus and CVD method for copper deposition

(76) Inventors: Akiko Kobayashi, Tokyo (JP); Tomoaki Koide, Tokyo (JP); Minjuan Zhang, Tokyo (JP); Atsushi Sekiguchi, Tokyo (JP); Osamu Okada, Kanagawa-ken (JP)

Correspondence Address: Platon N. Mandros, BURNS, DOANE, SWECKER & MATHIS, L.L.P., P.O. Box 1404, Alexandria, VA, 22313-1404, US

(21) Appl. No.: 09/785,459

(22) Filed: Feb. 20, 2001

Related U.S. Application Data
(62) Division of application No. 09/430,135, filed on Oct. 29, 1999.

(30) Foreign Application Priority Data
Nov. 4, 1998 (JP) 10-313489

(51) Int. Cl. C23C 16/06; B05D 1/36

(52) U.S. Cl. 427/99; 427/255.29; 427/255.7; 427/404; 118/715

(57) ABSTRACT

A CVD apparatus for depositing a copper interconnect film on a substrate is equipped with a first CVD module 15 which deposits a copper film as a foundation using a Cu(hfac)(tmvs)-based precursor material having a small film deposition rate, and a second CVD module 16 which performs film deposition to increase the thickness of the copper film using a Cu(hfac)(atms)-based precursor material having a large film deposition rate. The film deposition rate of the Cu(hfac)(tmvs)-based precursor material is about 100 nm per minute and the film deposition rate of the Cu(hfac)(atms)-based precursor material is about 400 nm per minute. This realizes a practical CVD apparatus for mass production which achieves both a high film deposition efficiency and high film quality.

### CROSS-REFERENCE TO RELATED APPLICATIONS

The present application claims the priority of Japanese Patent Application No. 10-313489, filed in Japan on Nov. 4, 1998, the entire subject matter of which is hereby incorporated herein by reference.

### BACKGROUND OF THE INVENTION

1. Field of the Invention

The present invention relates to a CVD apparatus and a CVD method, and in particular it relates to a CVD apparatus and a CVD method which deposits a copper interconnect film for the formation of large-scale integrated circuits on a silicon substrate by two CVD deposition processes—one to form a foundation and another to increase its thickness.

2. Discussion of Related Art

Copper CVD (chemical vapour-phase deposition or chemical vapour deposition) apparatus, which deposits a copper film for interconnection in semiconductor large-scale integrated circuits, has hitherto only been produced as experimental apparatus, and a single-substrate processing copper CVD apparatus suitable for mass production has yet to be perfected. When producing a single-substrate processing copper CVD apparatus for mass production, the deposition efficiency can be increased by increasing the film deposition rate in the deposition of copper interconnect films on substrates such as silicon, compound semiconductors and glass. The film quality can be increased by making the filling characteristics such as step coverage favorable.

Therefore, from the viewpoint of achieving a high film deposition efficiency and high film quality, research has hitherto been undertaken into the optimum film deposition process configuration in single-substrate processing copper CVD apparatus, the number of steps, the number of film deposition modules, their structure, and so on. However, in a single-substrate processing copper CVD apparatus for mass production, examples of desirable film deposition module configurations have yet to be decided upon.

At present, when depositing a copper interconnect film on a substrate in a CVD apparatus, there is generally a trade-off between the deposition rate and the filling characteristics if the film deposition is performed in a single process (a single set of film deposition conditions in a single deposition chamber). It is thus very difficult to perform film deposition while satisfying the requirements both for high deposition rate and good filling characteristics. Consequently, practical single-substrate processing copper CVD apparatus for mass production have yet to be perfected. In Japanese Patent Application No. H10-92399, filed on Mar. 20, 1998 and which corresponds to U.S. patent application Ser. No. 09/227,089, a practical single-substrate processing CVD apparatus and CVD method were disclosed that facilitate mass production. According to that disclosure, when performing film deposition of a metal interconnect film, the film deposition is performed by dividing it into two processes—a process which performs deposition under first deposition conditions having a small deposition rate and good filling characteristics, and a process which performs film deposition under second deposition conditions having a large deposition rate and poor filling characteristics. The entire subject matter of U.S. patent application Ser. No. 09/227,089 is hereby incorporated herein by reference.

### OBJECTS AND SUMMARY

The present invention aims to provide a CVD apparatus and a CVD method that facilitate CVD deposition with improved deposition rate and film quality by performing film deposition using precursor materials that are respectively suited to each of the two CVD processes under different deposition conditions in depositing a copper interconnect film on a substrate, thereby realizing favorable embedding characteristics and a large deposition rate.

According to the present invention, specific proposals are made for the precursor materials suitable for the deposition process under the first deposition conditions, and for the precursor materials suitable for the deposition process under the second deposition conditions. In the Japanese Patent Application No. H10-92399, the first deposition conditions and second deposition conditions were associated based on the trade-off between the magnitude of the deposition rate and the quality of the embedding characteristics are. However, considering the deposition of an actual copper interconnect film, there is no need to strongly consider the abovementioned trade-off, and it is possible to deposit an entire copper interconnect film in two processes by appropriately setting the different deposition conditions based principally just on the magnitude of the deposition rate.

To achieve the abovementioned aims, the CVD apparatus and CVD method relating to the present invention are configured as follows.

In the deposition of copper interconnect films on a substrate, the CVD apparatus comprises a first CVD module which deposits a foundation copper film using a Cu(hfac)(tmvs)-based precursor material at a low deposition rate, and a second CVD module which performs a deposition, to make the abovementioned copper film thicker using a Cu(hfac)(atms)-based precursor material at a large deposition rate.

In the abovementioned CVD apparatus, the single CVD deposition process which deposits the copper interconnect film is divided into sub-processes based on two precursor materials with different deposition rates. The deposition rate of the Cu(hfac)(tmvs)-based precursor material is about 100 nm per minute, and the deposition rate of the Cu(hfac)(atms)-based precursor material is about 400 nm per minute. Each sub-process is executed in each of the first and second CVD modules, respectively. This results in a CVD apparatus for mass production that has the useful property of being able to achieve both increased film deposition efficiency and improved film quality.

A CVD apparatus having the abovementioned configuration is configured so that a single film deposition process is completed by the combination of a film deposition process using a Cu(hfac)(tmvs)-based precursor material and a film deposition process using a Cu(hfac)(atms)-based precursor material. A single film deposition process is executed with the first film deposition process and second film deposition process as sub-processes. Consequently, CVD modules are prepared corresponding to their respective precursor materials.

It is also possible to provide a single CVD deposition chamber and to configure it in such a way that this single film deposition chamber is used in common as the respective film deposition chambers of the abovementioned first CVD module and second CVD module. Naturally, it goes without saying that the first CVD module and second CVD module could-also be configured by providing them with dedicated film deposition chambers.

A CVD method of the present invention includes depositing a copper interconnect film on a substrate, and is configured so as to complete a single film deposition process by sequentially executing a first CVD process which deposits a foundation copper film having good embedding characteristics using a Cu(hfac)(tmvs)-based precursor material having a small film deposition rate, and a second CVD process which performs film deposition for increasing the thickness of the abovementioned copper film using a Cu(hfac)(atms)-based precursor material having a large deposition rate.

### BRIEF DESCRIPTION OF THE FIGURES

FIG. 1 is a plan view showing a typical embodiment of a CVD apparatus according to the present invention.

FIG. 2 is a cross sectional view of one example of an interconnect structure and the state of film deposition according to the present invention.

FIG. 3 is a plan view showing an alternative embodiment of a CVD apparatus according to the present invention.

### DETAILED DESCRIPTION OF THE PREFERRED EMBODIMENTS

Preferred embodiments of the present invention are described below based on the accompanying figures.

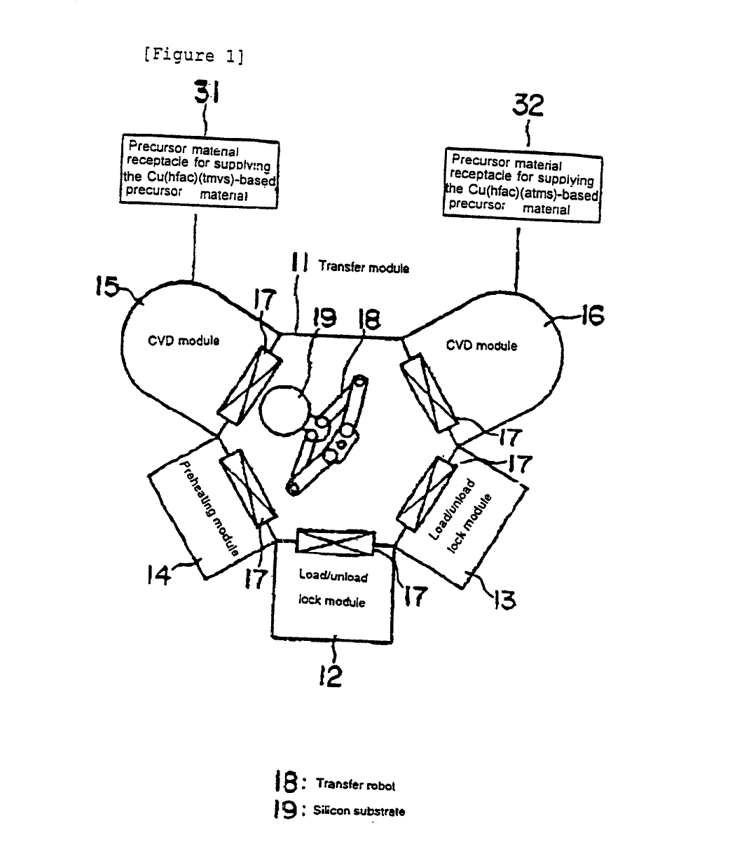

FIG. 1 shows a preferred embodiment of a CVD apparatus relating to the present invention. FIG. 1 is a top view of a multi-chamber CVD apparatus equipped with a plurality of modules 12, 13, 14, 15, 16 of various types around a centrally-located transfer module 11. Here, “module” refers to a constituent part of an apparatus/machine/system that is a functionally unified part. Gate valves 17 are provided between the chambers of transfer module 11 and each of the modules 12 to 16.

A transfer robot (substrate transfer mechanism) 18 is provided in the chamber of transfer module 11. The transfer robot 18 uses its hand to load silicon substrates 19 into each module and to unload them from each module. The plurality of modules disposed around the transfer module 11 are two load/unload lock modules 12 and 13, a preheating module 14, a first CVD module 15 (referred to in the following as “first CVD module 15”), and a second CVD module 16 (referred to in the following as “second CVD module 16”). These modules 12 to 16 are respectively equipped with chambers into which the silicon substrate 19 can be loaded. In particular, the first CVD module 15 and the second CVD module 16 are respectively equipped with dedicated film deposition chambers. Furthermore, the first CVD module 15 and the second CVD module 16 each includes various other apparatus configurations necessary for film deposition. The CVD modules 15, 16 may be modules that perform film deposition by thermal CVD, for example, and which deposit a copper interconnect film on an interconnect pattern (interconnect structure) formed on the surface of the silicon substrate 19. In the first CVD module 15, film deposition is performed under first film deposition conditions using a precursor material that at least has a relatively small film deposition rate, and in the second CVD module 16, film deposition is performed under second film deposition conditions using a precursor material that at least has a relatively large film deposition rate.

In a preferred embodiment, the CVD modules 15, 16 may be of the type disclosed in copending U.S. patent application Ser. No. 08/905,766, the entire subject matter of which is hereby incorporated herein by reference.

A Cu(hfac)(tmvs)-based precursor material, such as trimethylvinylsilyl hexafluoroacethylacetonate copper (I), is preferably used as the precursor material with a small deposition rate under the first deposition conditions, and a Cu(hfac)(atms)-based precursor material, such as allyltrimethylsilyl hexafluoroacethylacetonate cooper (I), is preferably used as the precursor material with a large deposition rate under the second deposition conditions. Accordingly, a precursor material receptacle 31 for supplying the Cu(hfac)(tmvs)-based precursor material is fitted in the first CVD module 15, and a precursor material receptacle 32 for supplying the Cu(hfac)(atms)-based precursor material is fitted in the second CVD module 16.

The deposition rate of the Cu(hfac)(tmvs)-based precursor material is about 100 nm per minute and it has a good initial nucleation characteristic, whereas the deposition rate of the Cu(hfac)(atms)-based precursor material is about 400 nm per minute and it has a poor initial nucleation characteristic that is not as good as the nucleation characteristic of the Cu(hfac)(tmvs)-based precursor. In the film deposition of the Cu(hfac)(atms)-based precursor material, a foundation of copper is required.

Nucleation refers to the initial stages thin film development, and relates to the size of the film grains. Specifically, in a good or small nucleation, very small grains are distributed densely and uniformly. Good nucleation facilitates conformal step coverage for trenches and throughholes.

In the first CVD module 15 which performs film deposition using the Cu(hfac)(tmvs)-based precursor material having a small film deposition rate, CVD film deposition is performed in order to embed a copper film for use as a foundation in the interconnect pattern on the silicon substrate 19. Also, in the second CVD module 16 which performs film deposition using the Cu(hfac)(atms)-based precursor material having a large film deposition rate, CVD film deposition is performed in order to increase the thickness of the copper film that was thinly deposited by the first CVD module 15 as a foundation. With the film deposition in the second CVD module 16, a copper interconnect film is deposited at a high speed on the silicon substrate 19, for example a copper film of thickness 1 μm or thereabouts is formed in a short time.

The film deposition temperature can be set relatively low in the abovementioned first film deposition conditions, and the film deposition temperature can be set relatively high in the abovementioned second film deposition conditions. Alternatively, the first and second film deposition conditions can be made the same. The abovementioned film deposition temperature is essentially determined by the substrate temperature. Note that although film deposition by thermal CVD has been assumed in the above, it is not limited thereto. Other CVD techniques that are configured so that the film deposition conditions can be set differently are also possible.

In the abovementioned CVD apparatus, a single silicon substrate 19 that has been set in a cassette (not illustrated) is loaded by the-transfer robot 18 from one load/unload lock module 12 into the preheating module 14, where it is heated to about 175° C., and after that it is loaded into the first CVD module 15. The first CVD module 15 is preferably set to a film deposition temperature of about 175° C. After film deposition has been performed for about two minutes, the silicon substrate 19 is unloaded from the first CVD module 15 and transferred to the second CVD module 16 by the transfer robot 18. The second CVD module 16 is preferably set to a film deposition temperature of about 190° C. After film deposition has been performed for about one minute, silicon substrate 19 is unloaded from the second CVD module 16 and is returned to the load/unload lock module 13 by transfer robot 18.

In both the first CVD module 15 and the second CVD module 16, the aforementioned film deposition processes are preferably conducted at two torr and with the respective precursor material being introduced at the rate of two grams per minute.

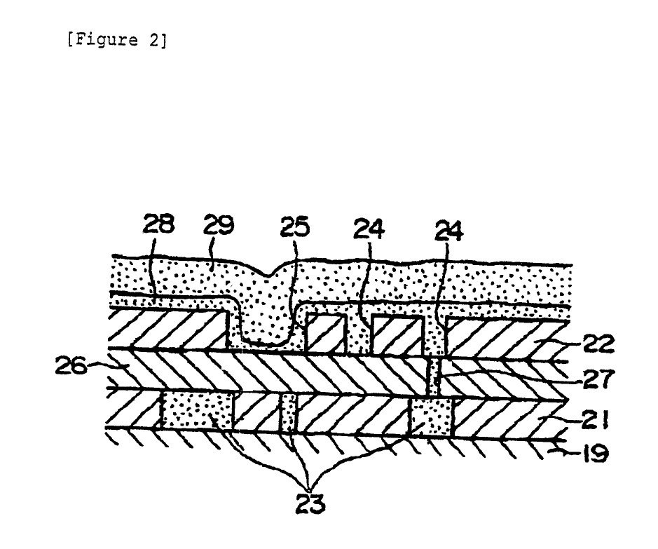

The deposition of a copper film as executed by the abovementioned CVD apparatus is now described with reference to FIG. 2. FIG. 2 shows the state where film deposition in the first and second CVD film deposition modules has already been completed. In FIG. 2, items 21 and 22 are pattern layers for interconnect formation which are layered on the silicon substrate 19, item 23 is the interconnect (copper) formed on the underside, and items 24 and 25 are interconnect trenches (channels) formed on the upper pattern layer 22. The interconnect trench 24 is a narrow trench and the interconnect trench 25 is a wide trench. An isolation layer 26 is formed between the pattern layers 21 and 22, and a via-hole 27 is formed in the isolation layer 26. To form the interconnect in the upper pattern layer 22, a CVD apparatus according to the present invention is used. At the upper pattern layer 22, a copper film 28 is deposited at the bottom by the first CVD module 15, and a copper film 29 is deposited thereupon by the second CVD module 16. The interconnect 23 formed at the bottom is electrically connected to the copper film forming the upper interconnect by copper deposited inside via-hole 27.

In the interconnect structure shown in FIG. 2, on the pattern layer forming the interconnect structure, the abovementioned wide trench 25 having, for example, a width of 1.5 μm (microns) and a depth of 0.5 μm, the abovementioned narrow trench 24 having a width of 0.3 μm and a depth of 0.5 μm, and the abovementioned minute via-hole 27 having a diameter of 0.2 μm and a depth of 0.5 μm are formed together.

With the abovementioned CVD apparatus, film deposition is first performed for about two minutes on the silicon substrate 19 in first CVD module 15 using a Cu(hfac)(tmvs)-based precursor material having a small film deposition rate, whereby the copper film 28 with a 200 nm thickness is deposited. Since the film deposition in the first CVD module 15 has good embedding characteristics, the via-holes having a diameter of 0.3 μm, or less, and interconnect trenches having a width of 0.35 μm, or less, are completely filled with a copper film. Accordingly, as shown in FIG. 2, the minute via-hole 27 and the narrow trench 24 are filled. On the other hand, the wide trench 25 is subjected to conformal film deposition to a depth of 200 nm at this stage, but the filling with copper film 28 is not complete.

Next, the silicon substrate 19 is transferred to the second CVD module 16 and is subjected to film deposition for about one minute in the second CVD module 16 using a Cu(hfac)(atms)-based precursor material having a high film deposition rate, whereby a copper film 29 of thickness 400 nm is deposited. In this film deposition, the abovementioned copper film 28 is used as a foundation, and the presence of copper film 29 facilitates CVD film deposition using the Cu(hfac)(atms)-based precursor material whereby copper film 28 is deposited. In FIG. 2, the copper film 28 and the copper film 29 are depicted as separate layers, but as copper films they are essentially the same thing. Accordingly, the CVD film deposition of copper by the second CVD module 16 serves the purpose of increasing the overall thickness of the copper film 28, and it is able to form a copper film at a high speed. Also, with the film deposition by the second CVD module 16, a copper film is deposited to a thickness of 600 nm in addition to the 200 nm copper film 28 deposited by CVD module 15, even in the wide trench 25.

If one tries to use a film deposition process with a single set of film deposition conditions to embed copper in an interconnect pattern where miniature via holes, narrow trenches and wide trenches co-exist, this would have to be done in the first CVD module 15 which has film deposition conditions with favourable embedding characteristics. But since the film deposition rate is small under these conditions, the deposition of 1.1 μm (trench depth: 1.0 μm, plus a thickness of film deposition to ensure excess embedding: 0.1 μm) would require a long film deposition time of 12 minutes and 30 seconds. On the other hand, in the abovementioned embodiment, where the first and second CVD modules 15 and 16 are provided, a Cu(hfac)(tmvs)-based precursor material with a small film deposition rate is used in the first CVD module to reliably embed an interconnect pattern and, using this pattern as a foundation for the subsequent copper film formation, the copper film 28 is used as a foundation in the second CVD module 16 to form and facilitate the formation of a copper film using a Cu(hfac)(atms)-based precursor material having a large film deposition rate and to deposit a thick copper film. As described above, when an interconnect structure is made by depositing a copper film on an interconnect pattern in which minute holes, narrow trenches and wide trenches coexist, it is possible to use a CVD apparatus equipped with the CVD modules 15 and 16 according to the present embodiment to fill with the copper film completely and at high speed, and the copper film can be deposited in 5 minutes.

Although one embodiment of the present invention has been described using FIG. 2, the copper film is frequently formed after depositing a barrier layer and/or bonding layer before forming the copper layer. The essential point of the present invention is the pattern formation, and so the illustration and description of the barrier layer and/or bonding layer have been omitted.

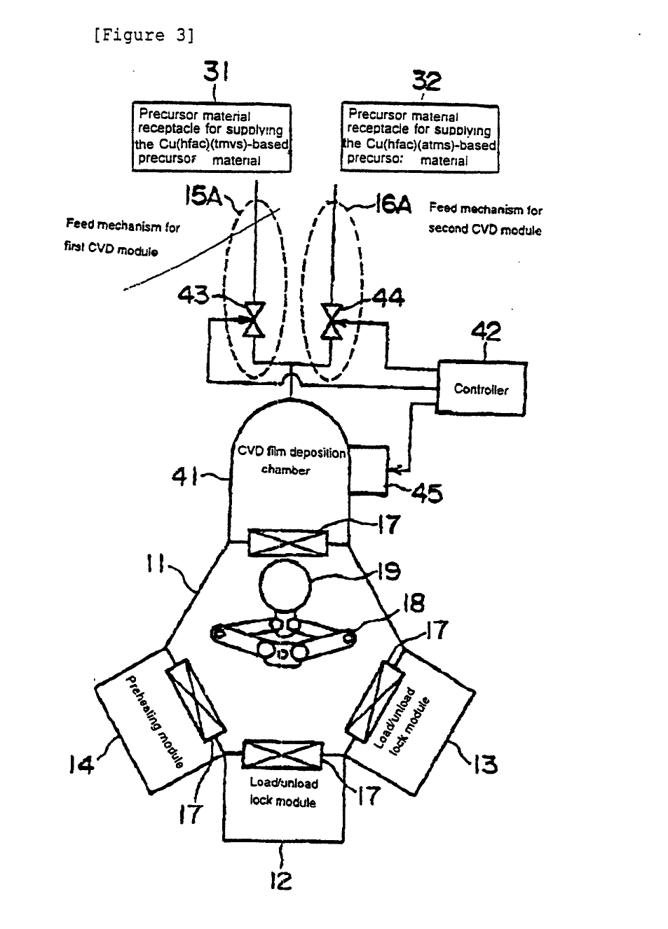

Next, an alternative embodiment of a CVD apparatus relating to the present invention is described with reference to FIG. 3. In this embodiment, a single CVD film deposition chamber 41 is provided as the chamber for the CVD apparatus around the transfer module 11. CVD film deposition chamber 41 is configured so that it is supplied with a Cu(hfac)(tmvs)-based precursor material from the precursor material receptacle 31 via a feed mechanism 15A for the first CVD module, and is supplied with a Cu(hfac)(atms)-based precursor material from the precursor material receptacle 32 via a feed mechanism 16A for the second CVD module. Which of the precursor materials is supplied to CVD film deposition chamber 41 is determined under the control of a controller 42. The feed mechanism 15A for the first CVD module and the feed mechanism 16A for the second CVD module are respectively provided with switching valves 43 and 44 in their supply paths. The switching action of switching valves 43 and 44 is controlled by a controller 42.

The abovementioned first CVD module is configured by the feed mechanism 15A for the first CVD module and CVD film deposition chamber 41, and the abovementioned second CVD module is configured by feed mechanism 16A for the second CVD module and CVD film deposition chamber 41. It is clear from the above configuration that CVD film deposition chamber 41 is used in common as the film deposition chamber of the abovementioned first CVD module and second CVD module. The CVD film deposition by the first CVD module using a Cu(hfac)(tmvs)-based precursor material and the CVD film deposition by the second CVD module using a Cu(hfac)(atms)-based precursor material are performed in the same way as mentioned above under the control of controller 42. Note that the abovementioned first and second film deposition conditions in the CVD film deposition chamber 41 are each set-by the controller 42 controlling condition setting equipment 45. Also note that a program for implementing the CVD method relating to the present invention is stored in a memory of the controller 42. The CVD film deposition method is the same as stated above, so its description is omitted here.

With the present invention as clearly shown in the above description, in, for example, a single-substrate CVD apparatus or CVD method which deposits a copper interconnect film on a silicon substrate, a single CVD process is performed by the combination of a process with a small film deposition rate and a process with a large film deposition rate, so that good film deposition rate characteristics and embedding characteristics are achieved, the film deposition efficiency and film quality can be improved, and it is possible to realize an efficient production method for semiconductor devices that achieves high productivity.

Although only preferred embodiments are specifically illustrated and described herein, it will be appreciated that many modifications and variations of the present invention are possible in light of the above teachings and within the purview of the appended claims without departing from the spirit and intended scope of the invention.

What is claimed is:

1. A CVD apparatus that deposits a copper interconnect film on a substrate, comprising:
a first CVD module that includes first means for performing film deposition with a Cu(hfac)(tmvs)-based precursor material, and
a second CVD module that includes second means for performing film deposition with a Cu(hfac)(atms)-based precursor material.

2. The CVD apparatus according to claim 1, wherein the first performing means performs a foundation copper film deposition process using the said Cu(hfac)(tmvs)-based precursor material, and the second performing means increases a thickness of the foundation copper film deposition using the Cu(hfac)(atms)-based precursor material.

3. The CVD apparatus according to claim 1, wherein the apparatus includes a single CVD deposition chamber, the single CVD deposition chamber being used as the deposition chamber of the said first CVD module and the deposition chamber of the second CVD module.

4. The CVD apparatus according to claim 2, wherein the apparatus includes a single CVD deposition chamber, the single CVD deposition chamber being used as the deposition chamber of the said first CVD module and the deposition chamber of the second CVD module.

5. A CVD apparatus that deposits a copper interconnect film on a substrate, comprising:
a first CVD module that includes first means for performing film deposition with a first Cu based precursor material having a first nucleation characteristic and which has a first deposition rate, and
a second CVD module that includes second means for performing film deposition with a second Cu based precursor material having a second nucleation characteristic that is larger than the first nucleation characteristic and which has a second deposition rate that is higher than the first deposition rate.

6. The CVD apparatus according to claim 5, wherein the first performing means performs a foundation copper film deposition process using the first Cu based precursor material, and the second performing means increases a thickness of the foundation copper film deposition using the second Cu based precursor material.

7. The CVD apparatus according to claim 5, wherein the apparatus includes a single CVD deposition chamber, the single CVD deposition chamber being used as the deposition chamber of the said first CVD module and the deposition chamber of the second CVD module.

8. The CVD apparatus according to claim 6, wherein the apparatus includes a single CVD deposition chamber, the single CVD deposition chamber being used as the deposition chamber of the said first CVD module and the deposition chamber of the second CVD module.

9. A CVD method of depositing a copper interconnect film on a substrate, the method comprising the steps of:
executing a first CVD process which deposits a foundation copper film using a Cu(hfac)(tmvs)-based precursor material, and
sequentially executing a second CVD process which increases a thickness of the foundation copper film using a Cu(hfac)(atms)-based precursor material.

10. The method of claim 9, wherein the first and second CVD processes together constitute a single deposition process.

11. The method of claim 9, wherein a deposition rate of the second CVD process is higher than a deposition rate of the first CVD process.

12. The method of claim 9, wherein the deposition rate of the first CVD process is about 100 nm per minute at two torr when the precursor is delivered at two grams per minute.

13. The method of claim 9, wherein the deposition rate of the second CVD process is about 400 nm per minute at two torr when the precursor is delivered at two grams per minute.

14. The method of claim 12, wherein the deposition rate of the second CVD process is about 400 nm per minute at two torr when the precursor is delivered at two grams per minute.

15. A CVD method of depositing a copper interconnect film on a substrate, the method comprising the steps of:
executing a first CVD process which deposits a foundation copper film using a first Cu based precursor material having a first nucleation characteristic and a first deposition rate, and
sequentially executing a second CVD process which increases a thickness of the foundation copper film using a second Cu based precursor material having a second nucleation characteristic that is larger than the first nucleation characteristic and which has a second deposition rate that is higher than the first deposition rate.

16. The method of claim 15, wherein the first and second CVD processes together constitute a single deposition process.

17. The method of claim 15, wherein a deposition rate of the second CVD process is higher than a deposition rate of the first CVD process.

18. The method of claim 15, wherein the deposition rate of the first CVD process is about 100 nm per minute at two torr when the precursor is delivered at two grams per minute.

19. The method of claim 15, wherein the deposition rate of the second CVD process is about 400 nm per minute at two torr when the precursor is delivered at two grams per minute.

20. The method of claim 18, wherein the deposition rate of the second CVD process is about 400 nm per minute at two torr when the precursor is delivered at two grams per minute.
